(19) United States
(12) Patent Application Publication
(10) Pub. No.: US 2024/0429283 A1
(43) Pub. Date: Dec. 26, 2024

(54) BACKSIDE EPITAXY FOR SEMICONDUCTOR STRUCTURES

(71) Applicant: International Business Machines Corporation, Armonk, NY (US)

(72) Inventors: Alexander Reznicek, Troy, NY (US); Sagarika Mukesh, Albany, NY (US); Tsung-Sheng Kang, Ballston Lake, NY (US); Ruilong Xie, Niskayuna, NY (US)

(21) Appl. No.: 18/337,787

(22) Filed: Jun. 20, 2023

(51) Int. Cl. H01L 29/08; H01L 21/8238; H01L 27/092; H01L 29/417; H01L 29/423; H01L 29/66; H01L 29/775; H01L 29/786

(52) U.S. Cl. CPC H01L 29/0847; H01L 21/823814; H01L 21/823871; H01L 27/092; H01L 29/41733; H01L 29/42392; H01L 29/66439; H01L 29/66545; H01L 29/775; H01L 29/78696; H01L 21/823807; H01L 29/0673

(57) ABSTRACT

Embodiments are disclosed for a semiconductor structure. The semiconductor structure includes a field effect transistor (FET). The FET includes a source/drain (S/D) epitaxy and a metal gate. Additionally, the semiconductor structure includes a backside epitaxy in electrical contact with the S/D epitaxy. Further, the backside epitaxy includes a highly doped epitaxy. Additionally, the semiconductor structure includes a backside contact in electrical contact with the backside epitaxy. Further, the semiconductor structure includes a backside power distribution network in electrical contact with the backside contact.

### BACKGROUND

The present invention generally relates to semiconductor structures, and more particularly to backside epitaxy for semiconductor structures.

Integrated circuit (IC) chips are formed on semiconductor wafers at increasingly smaller scale. In current technology nodes, such as 7, 10 and 14 nanometer technologies, transistor devices are constructed as three-dimensional (3D) fin field effect transistor (FINFET) structures. However, chipmakers face a myriad of challenges at 5 nm, 3 nm and beyond. Currently, traditional chip scaling continues to slow as process complexities and costs escalate at each node.

### SUMMARY

Embodiments are disclosed for a semiconductor structure. The semiconductor structure includes a field effect transistor (FET). The FET includes a source/drain (S/D) epitaxy and a metal gate. Additionally, the semiconductor structure includes a backside epitaxy in electrical contact with the S/D epitaxy. Further, the backside epitaxy includes a highly doped epitaxy. Additionally, the semiconductor structure includes a backside contact in electrical contact with the backside epitaxy. Further, the semiconductor structure includes a backside power distribution network in electrical contact with the backside contact.

Embodiments are disclosed for a method of fabricating a semiconductor structure. The method includes forming a placeholder between neighboring field effect transistors on a substrate of the semiconductor structure. Additionally, the method includes generating a source/drain (S/D) epitaxy by performing an epitaxial growth on the placeholder. Further, the method includes flipping a carrier wafer that includes the placeholder. Additionally, the method includes selectively etching the placeholder. Further, the method includes generating a backside epitaxy by performing backside epitaxial growth of a highly-doped epitaxy on the S/D epitaxy, wherein the backside epitaxy is polygon-shaped. Additionally, the method includes forming a backside contact in electrical contact with the backside epitaxy.

The present Summary is not intended to illustrate each aspect of, every implementation of, and/or every embodiment of the present disclosure. These and other features and advantages will become apparent from the following detailed description of the present embodiment(s), taken in conjunction with the accompanying drawings.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are illustrative of certain embodiments and do not limit the disclosure.

FIG. 1A is a cross-sectional view of semiconductor structures during intermediate steps of a method for fabricating a semiconductor structure having backside epitaxy, in accordance with some embodiments of the present disclosure.

FIG. 1B is a cross-sectional view of semiconductor structures during intermediate steps of a method for fabricating a semiconductor structure having backside epitaxy, in accordance with some embodiments of the present disclosure.

FIG. 1C is a cross-sectional view of semiconductor structures during intermediate steps of a method for fabricating a semiconductor structure having backside epitaxy, in accordance with some embodiments of the present disclosure.

FIG. 1D is a cross-sectional view of an example semiconductor structure having backside epitaxy, in accordance with some embodiments of the present disclosure.

FIG. 1E is a cross-sectional view of an example semiconductor structure having backside epitaxy, in accordance with some embodiments of the present disclosure.

FIG. 2 is a process flow chart of a method for fabricating a semiconductor structure having backside epitaxy, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the example embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub lithographic” may refer to a dimension or size less than current dimensions achievable by photolithographic processes, and the term “lithographic” may refer to a dimension or size equal to or greater than current dimensions achievable by photolithographic processes. The sub lithographic and lithographic dimensions may be determined by a person of ordinary skill in the art at the time the application is filed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device having a dummy fin removed from within an array of tight pitch fins according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Field effect transistors include a source, gate, and a drain. The source and drain can be a source/drain epitaxial growth (S/D epitaxy) that connects a gate with a metal-filled backside contact. However, the source and the drain can represent a bottleneck for current due to contact resistance between the S/D and the contact on the backside of the semiconductor structure.

Accordingly, some embodiments of the present disclosure include a semiconductor structure having a highly-doped epitaxy with a polygon shape. In such embodiments, the highly-doped epitaxy can be in electrical contact with an S/D epitaxy and a metal backside contact. In this way, such embodiments can increase the contact area between the source/drain (S/D) epitaxial. Increasing the contact area with the backside contact can reduce contact resistance between the S/D epitaxies and the backside contact. Additionally, using a highly doped material for the backside epitaxy can reduce current crowding. In these ways, such embodiments can improve the operation of semiconductor devices. However, some embodiments of the present disclosure may not achieve such advantages.

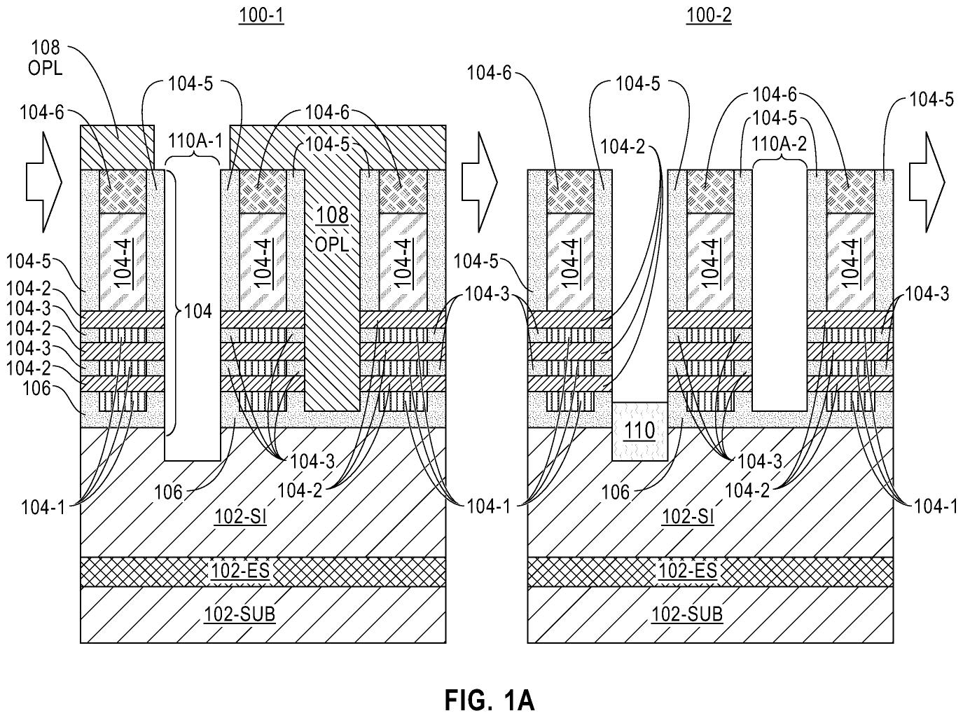

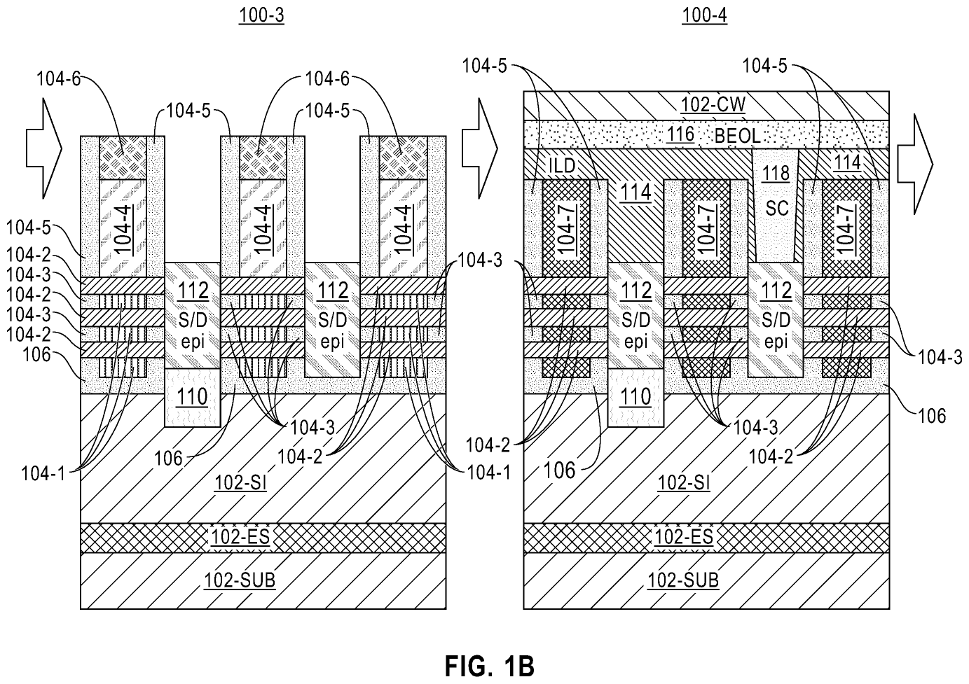

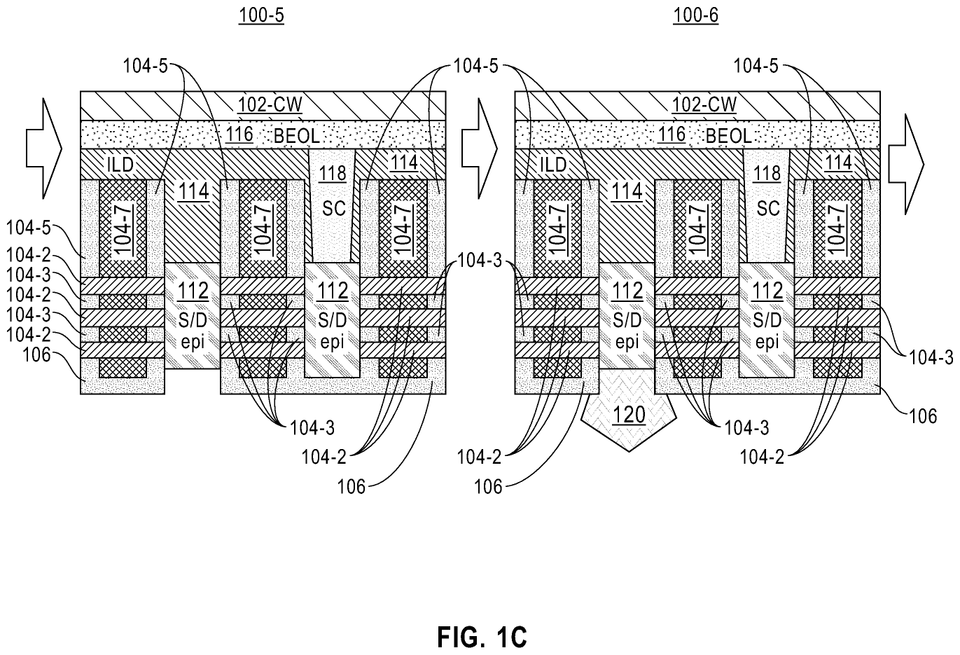

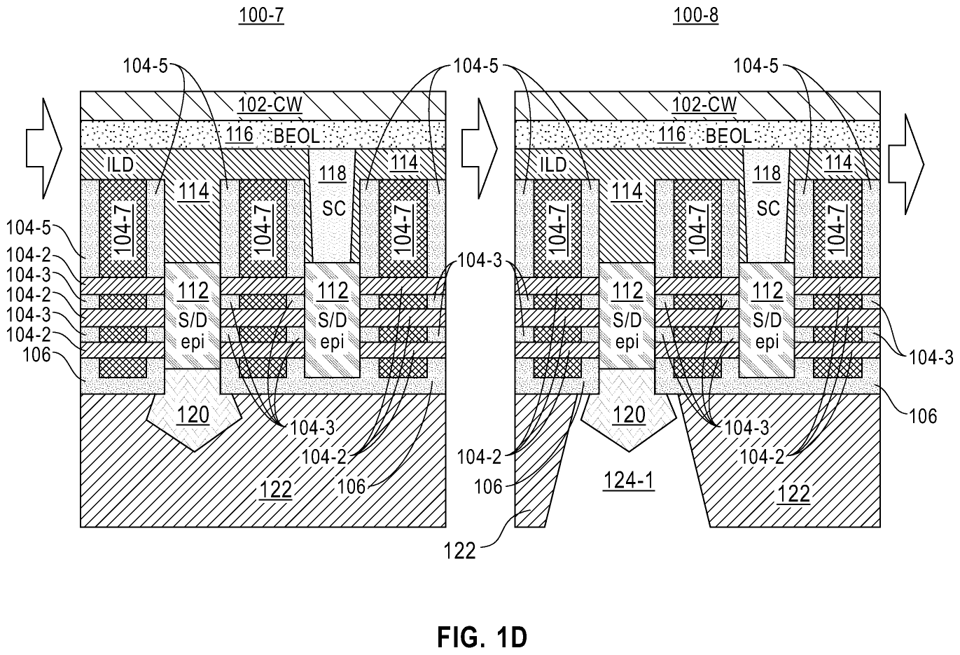

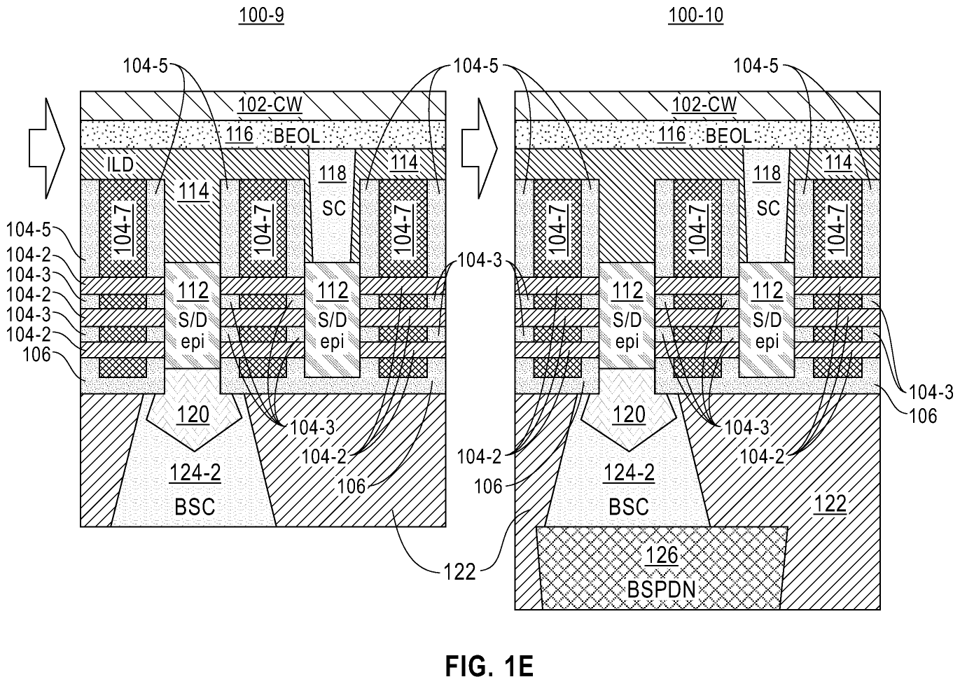

FIGS. 1A through 1E are cross-gate, cross-sectional views of example semiconductor structures 100-1 through 100-10 produced by a fabrication process of an example semiconductor structure that reduces contact resistance and current crowding by using a highly doped epitaxial growth that connects an S/D epitaxy with a backside contact. Highly doped can mean a doping concentration that is greater than 1.0×10²¹.

Additionally, FIGS. 1A through 1E include arrows indicating a direction from, and to, each other, which indicate the semiconductor structure to its right results from one or more steps of a fabrication process applied to the structure on its left. Further, for clarity, not all elements are labelled in these figures. Rather, representative elements are labelled, with similar elements being indicated by position, size, shape, hash lines (or lack thereof), and the like, in subsequent figures. Additionally, the semiconductor structures depicted in FIGS. 1A through 1E can represent any gate-all-around technology, including stacked FET, vertical transport FET (VTFET), forksheet devices, and the like.

FIG. 1A is a cross-sectional view of semiconductor structures 100-1, 100-2, during intermediate steps of a method for fabricating a semiconductor structure having backside epitaxy, in accordance with some embodiments of the present disclosure. The semiconductor structure 100-1 includes a substrate 102-SUB, etch stop layer 102-ES, silicon layer 102-SI, dummy gates 104, and organic planarization layer (OPL) 108.

The semiconductor structure 100-1 may result from a fabrication method wherein materials constituting each of these elements is deposited, applied, and otherwise arranged as shown. For example, the substrate 102-SUB, 102-SI can be a semiconductor or an insulator with an active surface semiconductor layer. The substrate 102-SUB, 102-SI can be crystalline, semi-crystalline, microcrystalline, or amorphous. The substrate 102-SUB, 102-SI can be essentially (e.g., except for contaminants) a single element (e.g., Si), primarily (e.g., with doping) of a single element, for example, Si or Ge, or the substrate 102-SUB, 102-SI can include a compound, for example, aluminum oxide (Al2O3), silicon dioxide (SiO2), gallium arsenide (GaAs), silicon carbide (SiC), or SiGe. The substrate 102-SUB, 102-SI can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 102-SUB, 102-SI can also have other layers forming the substrate 102-SUB, 102-SI, including high-k oxides and/or nitrides. In one or more embodiments, the substrate 102-SUB. 102-SI can be a silicon wafer. In an embodiment, the substrate 102-SUB, 102-SI can be a single crystal silicon wafer.

Further, the dummy gates 104 include sacrificial layers 104-1, channels 104-2, inner spacers 104-3, dummy gate material 104-4, spacers 104-5, hard mask 104-6, and bottom dielectric isolation (BDI) layer 106. Forming the dummy gates 104 can involve depositing sacrificial layers that serve as placeholders for gates. More specifically, a fabrication tool can form a patterned nanosheet stack over BDI layer 106. The patterned nanosheet stack includes sacrificial nanosheet layers 104-1, which may be composed of SiGe, for example. Additionally, the channels 104-2 can include nanosheet layers composed of Si, for example. Further, a fabrication tool may deposit dummy gate material 104-4 and gate hardmask 104-6 over the patterned nanosheet stack, and perform dummy gate patterning.

Additionally, the fabrication method can include lithography, wherein the OPL 108 is conformally applied to the gate stacks, in a pattern that protects the elements underneath from a lithography process that removes material from the elements not masked by the OPL 108. For example, the lithography process can remove the elements exposed (e.g., not protected) by the OPL 108, thus, creating the trench 101A-1 that exposes the spacers 104-5. Additionally, a selective mechanical etching can remove the underlying silicon layer 102-SI. In this way, the fabrication process can produce a trench 101A-1 that runs from the OPL 108, through the BDI layer 106, and into the silicon layer 102-SI.

As shown, the semiconductor structure 100-2 results from a forming a self-aligned placeholder 110 in the trench 101A-1 of the semiconductor structure 100-1. According to some embodiments of the present disclosure, the placeholder 110 may hold a place within the trench 101A-1 for a highly doped epitaxy produced during a subsequent fabrication process. As shown, the OPL 108 is relatively misaligned with the opening of the trench 101A-1. As such, the placeholder is self-aligned because the alignment of the trench 101A-1 is dependent upon the disposition of the spacers 104-5, not the OPL 108. The placeholder 110 may be composed of materials that can etch selective to silicon oxide and silicon nitride, such as organosilicate glass (SiCOH), amorphous silicon, tetraethyl orthosilicate (TEOS), and the like.

FIG. 1B is a cross-sectional view of semiconductor structures 100-3, 100-4 during intermediate steps of a method for fabricating a semiconductor structure having backside epitaxy, in accordance with some embodiments of the present disclosure. The semiconductor structure 100-3 results from removing the OPL 108 from the semiconductor structure 100-2, thus forming trench 101A-2. Additionally, the semiconductor structure 100-3 results from performing epitaxial growth in the trenches 101A-1, 101A-2 of the semiconductor structure 100-2, thus forming the S/D epitaxies 112. Performing the S/D epitaxial growth involves growing POR-doped semiconductor S/D epitaxy from exposed semiconductor surfaces (e.g., the nanosheet channels 104-2 and inner spacers 104-3).

Additionally, the semiconductor structure 100-4 results from replacement gate formation, middle of line (MOL) processing, and frontside processing on the semiconductor structure 100-3. Performing replacement gate formation includes removing the sacrificial layers 104-1 and dummy gate material 104-4, and replacing them with high-k metal gates 104-7. The high-k metal gates 104-7 provide the conductive gate electrode for the FETs. The materials for the gate structure may differ based on the type of device under construction (e.g., n-type or p-type).

Further, middle of line processing can involve depositing the interlayer dielectric (ILD) 114, and S/D contact 118. Additionally, performing the frontside processing can include forming the back end of line (BEOL) 116, and bonding a carrier wafer 102-CW. The processes and formation of MOL and BEOL structures is not within the scope of this disclosure and may be performed using known methods and techniques.

FIG. 1C is a cross-sectional view of semiconductor structures 100-5, 100-6 during intermediate steps of a method for fabricating a semiconductor structure having backside epitaxy, in accordance with some embodiments of the present disclosure. The semiconductor structure 100-5 results from flipping the semiconductor structure 100-4, removing the substrate layers to facilitate further processing on the back side of the wafer, and selectively etching the placeholder 110. As shown, the perspectives of the semiconductor structures 100-4, 100-5 are kept consistent for the sake of clarity, even though during fabrication, the semiconductor structure 100-5 is in a flipped position in comparison to the semiconductor structure 100-4. The removed substrate layers include substrate 102-SUB, etch stop layer 102-ES, and silicon layer 102-SI.

Further, semiconductor structure 100-6 results from performing backside epitaxial growth on the semiconductor structure 100-5, thus generating the backside epitaxy 120. The backside epitaxy 120 can be a highly doped epitaxy. Performing backside epitaxial growth includes growing highly-doped semiconductor S/D epitaxy from exposed semiconductor surfaces (e.g., the S/D epitaxy 112, inner spacers 104-3, and BDI layer 106). According to some embodiments of the present disclosure, the backside epitaxy 120 can be grown in a polygon structure, which provides increased contact area with a backside contact, in comparison to the contact area provided by the S/D epi 112 itself. It is noted that epitaxially grown semiconductor is lattice-matched, and as such, tend to have edges. However, one could form different shapes using masks and etches. Additionally, the highly doped epitaxy can reduce contact resistance and current crowding.

FIG. 1D is a cross-sectional view of an example semiconductor structure 100-7, 100-8 having backside epitaxy, in accordance with some embodiments of the present disclosure. The semiconductor structure 100-7 results from forming backside ILD 122. Forming the backside ILD 122 involves performing a backside ILD fill.

Further, semiconductor structure 100-8 results from forming a backside trench 124-1 on the semiconductor structure 100-7. Forming the backside trench 124-1 can involve chemical and/or mechanical etching to expose the polygonal surfaces of the backside epitaxy 120.

FIG. 1E is a cross-sectional view of an example semiconductor structure 100-9, 100-10 having backside epitaxy, in accordance with some embodiments of the present disclosure. The semiconductor structure 100-9 results from performing a metal fill on the semiconductor structure 100-8. More specifically, a fabrication tool may perform a metal fill in the backside trench 124-1 to form the backside contact (BSC) 124-2.

Additionally, the example semiconductor structure 100-10 results from forming a backside power distribution network (BSPDN) 126 on the semiconductor structure 100-9. The formation of the BSPDN 126 is not within the scope of this disclosure and may be performed using known methods and techniques.

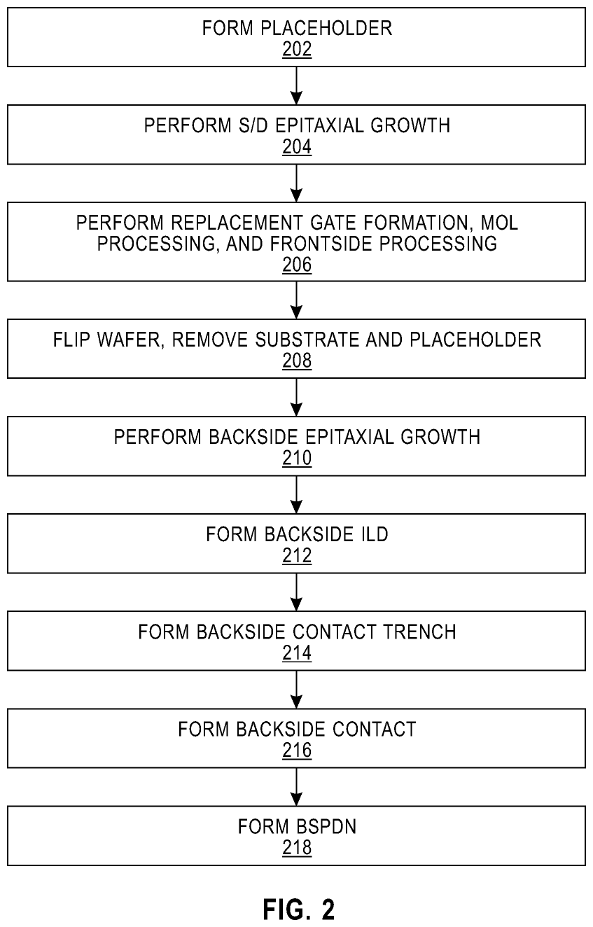

FIG. 2 is a process flow chart of a method 200 for fabricating a semiconductor structure having backside epitaxy, in accordance with some embodiments of the present disclosure. The method 200 may be similar to the method represented in FIGS. 1A through 1D, to produce a semiconductor structure, such as the example semiconductor structure 100-10 having backside epitaxy.

At operation 202, a fabrication tool may form a placeholder, such as the placeholder 110, described with respect to FIG. 1A. The operation 202 is represented with respect Forming the placeholder can involve depositing placeholder material within a trench, such as the trench 100A-1. The placeholder material may be any material that is etch selective to silicon oxide and silicon nitride, such as SiCOH, amorphous silicon, TEOS, and the like.

At operation 204, a fabrication tool may perform S/D epitaxial growth. As stated previously, performing the S/D epitaxial growth can involve growing POR-doped semiconductor S/D epitaxy from nanosheet channels 104-2 and inner spacers 104-3. The semiconductor structures generated by operations 202 and 204 are represented in FIG. 1A.

At operation 206, a fabrication tool can perform replacement gate formation, MOL processing, and frontside processing. As stated previously, replacement gate formation includes removing the sacrificial layers 104-1 and dummy gate material 104-4, and replacing them with high-k metal gates 104-7. Further, middle of line processing can involve depositing the interlayer dielectric (ILD) 114, and S/D contact 118. Additionally, performing the frontside processing can include forming the back end of line (BEOL) 116, and bonding a carrier wafer 102-CW to the semiconductor structure.

At operation 208, a fabrication tool can flip the wafer; and, remove the substrate and placeholder. Flipping the wafer can involve a vertical flip in the disposition of the semiconductor structure. Further, removing the substrate can involve removing the substrate layers to facilitate further processing on the back side of the wafer. Additionally, removing the placeholder can involve selectively etching the placeholder 110 from the semiconductor structure.

At operation 210, a fabrication tool can perform backside epitaxial growth. At stated previously, performing backside epitaxial growth includes growing highly-doped semiconductor S/D epitaxy from exposed semiconductor surfaces (e.g., the S/D epitaxy 112, inner spacers 104-3, and BDI layer 106). According to some embodiments of the present disclosure, the backside cpitaxy 120 can be grown in a polygon structure, which provides increased contact area with a backside contact, in comparison to the contact area provided by the S/D epi 112 itself. Additionally, the highly doped epitaxy can reduce contact resistance and current crowding. The semiconductor structures generated by operations 206 through 210 are represented in FIG. 1B.

At operation 212, a fabrication tool can form the backside ILD. Forming the backside ILD can involve depositing ILD material on the semiconductor structure.

At operation 214, a fabrication tool can form a backside contact trench. As stated previously, forming the backside contact trench can involve a chemical and/or mechanical process to remove backside ILD material to expose the polygonal sides of the backside epitaxy (backside epitaxy 120).

At operation 216, a fabrication tool can form the backside contact. Forming the backside contact can involve performing a metal fill of the backside contact trench.

At operation 218, a fabrication tool can form the BSPDN. Techniques for forming the BSPDN are well-known, and not further discussed. The semiconductor structures formed by operations 212 through 218 are represented in FIGS. 1C and 1D.

The terminology used herein is for the purpose of describing particular embodiments only and is not intended to be limiting of the various embodiments. As used herein, the singular forms “a.” “an,” and “the” are intended to include the plural forms as well, unless the context clearly indicates otherwise. It will be further understood that the terms “includes” and/or “including.” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks. When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category. For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations. Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A semiconductor structure comprising:
a field effect transistor (FET) comprising:
a source/drain (S/D) epitaxy; and
a metal gate;
a backside epitaxy in electrical contact with the S/D epitaxy, wherein the backside epitaxy comprises a highly doped epitaxy;
a backside contact in electrical contact with the backside epitaxy; and
a backside power distribution network in electrical contact with the backside contact.

2. The semiconductor structure of claim 1, wherein the semiconductor structure comprises a gate-all-around device.

3. The semiconductor structure of claim 2, wherein the gate-all-around device comprises a stacked FET device comprising the FET.

4. The semiconductor structure of claim 2, wherein the gate-all-around device comprises a vertical transport FET device comprising the FET.

5. The semiconductor structure of claim 2, wherein the gate-all-around device comprises a forksheet device comprising the FET.

6. The semiconductor structure of claim 1, wherein the backside epitaxy comprises a p-type epitaxy.

7. The semiconductor structure of claim 1, wherein the backside epitaxy comprises an n-type epitaxy.

8. The semiconductor structure of claim 1, wherein the highly doped epitaxy comprises a doping concentration greater than 1×10²¹.

9. The semiconductor structure of claim 1, wherein the backside epitaxy comprises a polygon shape that is lattice-matched.

10. A semiconductor structure comprising:
a gate-all-around device comprising:
a field effect transistor (FET) comprising:
a source/drain (S/D) epitaxy; and
a metal gate;
a backside epitaxy in electrical contact with the S/D epitaxy, wherein the backside epitaxy comprises a highly doped epitaxy, wherein the backside epitaxy comprises a polygon shape;
a backside contact in electrical contact with the backside epitaxy; and
a backside power distribution network in electrical contact with the backside contact.

11. The semiconductor structure of claim 10, wherein the gate-all-around device comprises a stacked FET device comprising the FET.

12. The semiconductor structure of claim 10, wherein the gate-all-around device comprises a vertical transport FET device comprising the FET.

13. The semiconductor structure of claim 10, wherein the gate-all-around device comprises a forksheet device comprising the FET.

14. The semiconductor structure of claim 10, wherein the backside epitaxy comprises a p-type epitaxy.

15. The semiconductor structure of claim 10, wherein the backside epitaxy comprises an n-type epitaxy.

16. The semiconductor structure of claim 10, wherein the highly doped epitaxy comprises a doping concentration greater than 1×10²¹.

17. A method for fabricating a semiconductor structure, the method comprising:
forming a placeholder between neighboring field effect transistors on a substrate of the semiconductor structure;
generating a source/drain (S/D) epitaxy by performing an epitaxial growth on the placeholder;
flipping a carrier wafer comprising the placeholder;
selectively etching the placeholder;
generating a backside epitaxy by performing backside epitaxial growth of a highly-doped epitaxy on the S/D epitaxy, wherein the backside epitaxy is polygon-shaped; and
forming a backside contact in electrical contact with the backside epitaxy.

18. The method of claim 17, wherein the highly-doped epitaxy comprises a doping concentration greater than 1×10²¹.

19. The method of claim 17, wherein the semiconductor structure comprises a gate-all-around device, and wherein the gate-all-around device is selected from a group consisting of:
a stacked FET device comprising the FET, a vertical transport FET device comprising the FET, and a forksheet device comprising the FET.

20. The method of claim 17, wherein the backside epitaxy comprises an epitaxy selected from a group consisting of a p-type epitaxy and an n-type epitaxy.
